(19) United States
(12) Patent Application Publication
(10) Pub. No.: US 2016/0233288 A1
(43) Pub. Date: Aug. 11, 2016

(54) ORGANIC LIGHT EMITTING DIODE DISPLAY

(71) Applicant: SAMSUNG DISPLAY CO., LTD., Yongin-si (KR)

(72) Inventors: Jung Kyu Lee, Seoul (KR); Do Hyun Kwon, Seongnam-si (KR); Dong Hwan Shim, Yongin-si (KR); Min Jung Lee, Seoul (KR); Seung-Hwan Cho, Yongin-si (KR)

(21) Appl. No.: 15/015,077

(22) Filed: Feb. 3, 2016

(30) Foreign Application Priority Data
Feb. 5, 2015 (KR) 10-2015-0018150

(51) Int. Cl. H01L 27/32

(52) U.S. Cl. CPC H01L 27/3276; H01L 27/3248; H01L 27/3265; H01L 27/3262; H01L 27/124

(57) ABSTRACT

Disclosed herein is provided an organic light emitting diode display, including: a substrate; a scan line on the substrate configured to transfer a scan signal; a data line crossing the scan line configured to transfer a data voltage; a driving power line crossing the scan line configured to transfer a driving voltage; a switching transistor connected to the scan line and the data line; a driving transistor connected to the switching transistor; and an organic light emitting diode electrically connected to the driving transistor, in which the driving power line is a storage electrode of a storage capacitor.

### CROSS-REFERENCE TO RELATED APPLICATION

This application claims priority to and benefit of Korean Patent Application No. 10-2015-0018150 filed in the Korean Intellectual Property Office on Feb. 5, 2015, the contents of which are herein incorporated by reference in their entirety.

### BACKGROUND

1. Field

Embodiments of the present disclosure are directed to an organic light emitting diode display device.

2. Description of the Related Art

An organic light emitting diode display includes two electrodes and an organic emission layer disposed therebetween, and forms excitons by combining electrons injected from one electrode with holes injected from the other electrode at the organic emission layer and emits light by allowing the excitons to emit energy.

The organic light emitting diode display includes a plurality of pixels each including an organic light emitting diode, which is a self-light emitting device, in which each pixel is provided with a plurality of transistors and a storage capacitor for driving the organic light emitting diode. The plurality of transistors basically include a switching transistor and a driving transistor.

The driving transistor controls a driving current flowing in the organic light emitting diode and stores a data voltage in the storage capacitor connected to a driving gate node of the driving transistor and keeps the stored data voltage for 1 frame. Therefore, the driving transistor supplies a constant amount of driving current to the organic light emitting diode for 1 frame to emit light.

However, a change in voltage of a data line or a scan signal of a scan line affects a voltage of a driving gate node of the driving transistor due to a parasitic capacitance formed between the driving gate node connected to a driving gate electrode of the driving transistor and the data line or a parasitic capacitance formed at an overlapping portion between the driving gate node of the driving transistor and the scan line. The change in voltage of the driving gate node changes a driving current flowing in the organic light emitting diode to cause a vertical crosstalk phenomenon which leads to a change in luminance.

To prevent or reduce the occurrence of this phenomenon, an interval between the data line and the driving gate node is formed to be as far away as possible, but as resolution is increased, a size of the pixel is reduced and a process design rule may not be continuously reduced due to a limitation of facility specification and photolithography process capability, such that there is a limitation in reducing or minimizing the vertical crosstalk.

The above information disclosed in this Background section is only for enhancement of understanding of the background and therefore it may contain information that does not form prior art.

### SUMMARY

Embodiments of the present disclosure can provide an organic light emitting diode display with reduced or minimized vertical crosstalk in a high resolution structure.

An embodiment of the present disclosure provides an organic light emitting diode display including: a substrate; a scan line on the substrate and configured to transfer a scan signal; a data line crossing the scan line, and configured to transfer a data voltage; a driving power line crossing the scan line and configured to transfer a driving voltage; a switching transistor connected to the scan line and the data line; a driving transistor connected to the switching transistor; and an organic light emitting diode electrically connected to the driving transistor, in which the driving power line is a storage electrode of a storage capacitor.

The driving power line may form the storage capacitor together with a driving gate electrode of the driving transistor.

The organic light emitting diode display may further include: a first gate insulating layer, an interlayer insulating layer, and a second gate insulating layer that are sequentially stacked on the substrate. The driving transistor may include: a first driving gate electrode on the interlayer insulating layer; and a second driving gate electrode on the second gate insulating layer.

The second driving gate electrode, along with the driving power line, may form the storage electrode of the storage capacitor.

The driving power line may overlap the second driving gate electrode on a second driving insulating layer.

The organic light emitting diode display may further include: an interlayer insulating layer, a gate insulating layer, and a passivation layer that are sequentially stacked on the substrate, in which the storage capacitor includes: a first storage electrode as a gate electrode on the gate insulating layer; and a second storage electrode as the driving power line.

The driving power line may be on the passivation layer.

The driving power line may be the second storage electrode, and overlap the gate electrode.

According to the organic light emitting diode display in accordance with an exemplary embodiment, it is possible to provide a structure capable of minimizing or reducing the crosstalk and improving the driving characteristics by using the driving power line as the storage electrode of the storage capacitor to increase the capacity of the storage capacitor.

### BRIEF DESCRIPTION OF THE DRAWINGS

FIG. 1 is a circuit diagram illustrating a pixel of an organic light emitting diode display according to an exemplary embodiment.

FIG. 2 is a timing diagram of a signal applied to one pixel of the organic light emitting diode display according to an exemplary embodiment.

FIG. 3 is a diagram schematically illustrating a plurality of transistors and a capacitor of an organic light emitting diode display according to another exemplary embodiment.

FIG. 4 is a layout view illustrating one pixel of an organic light emitting diode display according to the exemplary embodiment illustrated in FIG. 3.

FIG. 5 is a cross-sectional view of the organic light emitting diode display of FIG. 3 taken along the line V-V′.

### DETAILED DESCRIPTION

In the following detailed description, certain exemplary embodiments will be shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements (or components) throughout the specification.

Throughout this specification and the claims that follow, when it is described that an element or layer is “on,” “connected to,” “coupled” to,” “connected with,” “coupled with,” or “adjacent to” another element or layer, the element may be “directly on,” “directly connected to,” “directly coupled” to,” “directly connected with,” “directly coupled with,” or “directly adjacent to” the other element or one or more intervening elements or layers may be present. When an element or layer is referred to as being “directly on,” “directly connected to,” “directly coupled to,” “directly connected with,” “directly coupled with,” or “immediately adjacent to” another element or layer, there are no intervening elements or layers present.

The terminology used herein is for the purpose of describing particular embodiments only and is not intended to be limiting of the present invention. As used herein, the singular forms “a” and “an” are intended to include the plural forms as well, unless the context clearly indicates otherwise. In addition, unless explicitly described to the contrary, the words “include” and “comprise” as well as variations such as “includes,” “including,” “comprises,” or “comprising”, will be understood to imply the inclusion of stated elements (or components) but not the exclusion of any other elements (or components).

As used herein, the term “substantially,” “about,” and similar terms are used as terms of approximation and not as terms of degree, and are intended to account for the inherent deviations in measured or calculated values that would be recognized by those of ordinary skill in the art.

As used herein, the terms “use,” “using,” and “used” may be considered synonymous with the terms “utilize,” “utilizing,” and “utilized,” respectively.

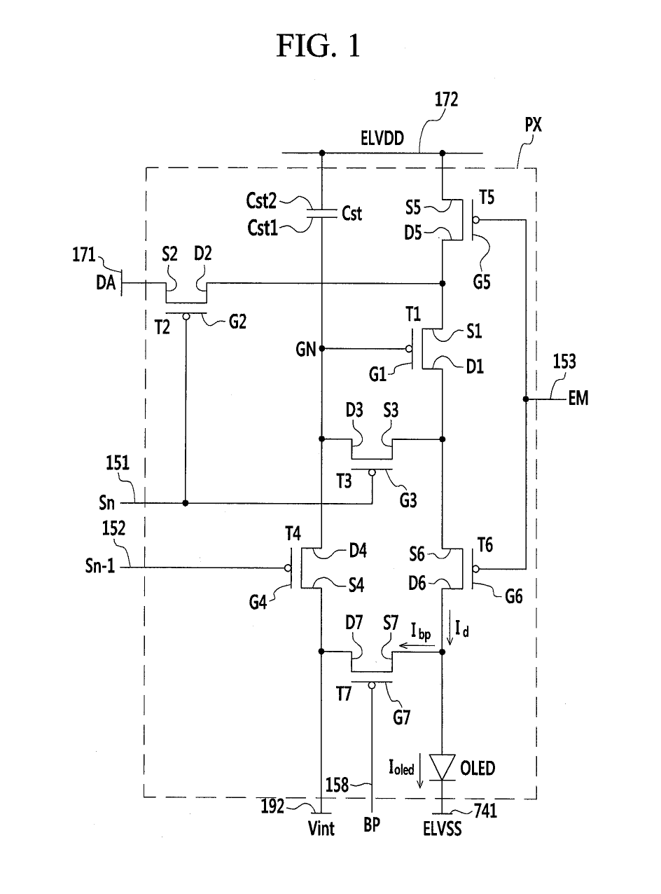

Hereinafter, an organic light emitting diode display according to an exemplary embodiment will be described with reference to FIGS. 1 to 5.

A pixel circuit of the organic light emitting diode display according to an exemplary embodiment will be described with reference to FIG. 1. Here, the pixel may refer to a smallest unit (e.g., minimum unit) for displaying an image.

FIG. 1 is a circuit diagram illustrating a pixel of an organic light emitting diode display according to an exemplary embodiment.

As illustrated in FIG. 1, a pixel Px of the organic light emitting diode display according to an exemplary embodiment includes a plurality of thin film transistors T1, T2, T3, T4, T5, T6, and T7, a plurality of wirings Sn, Sn-1, Sn-2, EM, Vint, DA, and ELVDD, which are selectively connected to the plurality of thin film transistors T1, T2, T3, T4, T5, T6, and T7, a storage capacitor Cst, and an organic light emitting diode OLED.

The plurality of thin film transistors T1, T2, T3, T4, T5, T6, and T7 include a first thin film transistor T1, a second thin film transistor T2, a third thin film transistor T3, a fourth thin film transistor T4, a fifth thin film transistor T5, a sixth thin film transistor T6, and a seventh thin film transistor T7.

Further, the plurality of thin film transistors T1, T2, T3, T4, T5, T6, and T7 include a driving transistor T1, a switching transistor T2, a compensation transistor T3, an initialization transistor T4, an operation control transistor T5, a light emission control transistor T6, and a bypass transistor T7.

A first gate electrode G1 of the first thin film transistor T1 is connected to a third drain electrode D3 of the third thin film transistor T3 and a fourth drain electrode D4 of the fourth thin film transistor T4, a first source electrode S1 is connected to a second drain electrode D2 of the second thin film transistor T2 and a fifth drain electrode D5 of the fifth thin film transistor T5, and a first drain electrode D1 is connected to a third source electrode S3 of the third thin film transistor T3 and a sixth source electrode S6 of the sixth thin film transistor T6.

A second gate electrode G2 of the second thin film transistor T2 is connected to a first scan line Sn, the second source electrode S2 is connected to a data line DA, and the second drain electrode D2 is connected to the first source electrode S1 of the first thin film transistor T1.

A third gate electrode G3 of the third thin film transistor T3 is connected to the first scan line Sn, the third source electrode S3 is connected to the first drain electrode D1 of the first thin film transistor T1, and the third drain electrode D3 is connected to the first gate electrode G1 of the first thin film transistor T1.

A fourth gate electrode G4 of the fourth thin film transistor T4 is connected to a second scan line Sn-1, a fourth source electrode S4 is connected to an initialization power line Vint, and the fourth drain electrode D4 is connected to the first gate electrode G1 of the first thin film transistor T1.

A fifth gate electrode G5 of the fifth thin film transistor T5 is connected to an emission control line EM, the fifth source electrode S5 is connected to a driving power line ELVDD, and the fifth drain electrode D5 is connected to the first source electrode S1 of the first thin film transistor T1.

A sixth gate electrode G6 of the sixth thin film transistor T6 is connected to the emission control line EM, a sixth source electrode S6 is connected to the first drain electrode D1 of the first thin film transistor T1, and a sixth drain electrode D6 is connected to the organic light emitting diode (OLED).

A seventh gate electrode G7 of the seventh thin film transistor T7 is connected to a third scan line Sn-2, which is a bypass control line through which a bypass signal BP is transferred, a seventh source electrode S7 is connected to the organic light emitting diode (OLED), and a seventh drain electrode D7 is connected to the fourth source electrode S4 of the fourth thin film transistor T4.

The plurality of wirings include a first scan line Sn, which transfers first scan signals to the second gate electrode G2 and the third gate electrode G3 of the second thin film transistor T2 and the third thin film transistor T3, respectively, a second scan line

Sn-1, which transfers a second scan signal to the fourth gate electrode G4 of the fourth thin film transistor T4, a third scan line Sn-2, which transfers a third scan signal to the seventh gate electrode S7 of the seventh thin film transistor T7, the emission control line EM, which transfers an emission control signal to the fifth gate electrode G5 and the sixth gate electrode G6 of the fifth thin film transistor T5 and the sixth thin film transistor T6, respectively, a data line (DA), which transfers a data signal to the second source electrode S2 of the second thin film transistor T2, a driving power line ELVDD, which supplies driving signals to one electrode of the storage capacitor Cst and the fifth source electrode S5 of the fifth thin film transistor T5, and an initialization power line Vint, which supplies an initialization signal to the fourth source electrode S4 of the fourth thin film transistor T4. Here, the data line D and the driving power line ELVDD may be formed as a data wiring.

Further, the storage capacitor Cst includes one electrode, which is connected to the driving power line ELVDD, and the other electrode, which is connected to the first gate electrode G1 and the third drain electrode D3 of the third thin film transistor T3.

The organic light emitting diode (OLED) includes a first electrode, a second electrode positioned on the first electrode, and an organic emission layer positioned between the first electrode and the second electrode. The first electrode of the organic light emitting diode (OLED) is connected to the seventh source electrode S7 of the seventh thin film transistor T7 and the sixth drain electrode D6 of the sixth thin film transistor T6, and the second electrode is connected to a common power supply ELVSS from which the common signal is supplied.

As an example of driving the pixel circuit, when the third scan signal, which is the bypass signal BP, is transferred to the third scan line Sn-2 to turn on the seventh thin film transistor T7, a residual current, flowing in the first electrode of the organic light emitting diode (OLED), exits to the fourth thin film transistor T4 through the seventh thin film transistor T7, such that the organic light emitting diode (OLED) suppresses light from being unexpectedly emitted due to the residual current flowing in the first electrode of the organic light emitting diode (OLED).

When the second scan signal is transferred to the second scan line Sn-1 and the initialization signal is transferred to the initialization power line Vint, the fourth thin film transistor T4 is turned on and thus an initialization voltage, corresponding to the initialization signal, is supplied to the first gate electrode G1 of the first thin film transistor T1 and the other electrode of the storage capacitor Cst through the fourth thin film transistor T4, such that the first gate electrode G1 and the storage capacitor Cst are initialized. The first thin film transistor T1 is turned on while the first gate electrode G1 is initialized.

When the first scan signal is transferred to the first scan line Sn and the data signal is transferred to the data line DA, the second thin film transistor T2 and third thin film transistor T3 are each turned on to supply a data voltage Vd, corresponding to the data signal, to the first gate electrode G1 through the second thin film transistor T2, the first thin film transistor T1, and the third thin film transistor T3. As the voltage is supplied to the first gate electrode G1, a compensation voltage {Vd+Vth, Vth is a negative (−) value), which is reduced as much as the threshold voltage Vth of the first thin film transistor from the data voltage Vd supplied from the first data line DA, is supplied. The compensation voltage (Vd+Vth) supplied to the first gate electrode G1 is supplied to the other electrode of the storage capacitor Cst, which is connected to the first gate electrode G1.

A driving voltage Vel, corresponding to the driving signal, is supplied from the driving power line ELVDD to one electrode of the storage capacitor Cst and the foregoing compensation voltage (Vd+Vth) is supplied to the other electrode thereof, and thus the storage capacitor Cst is stored with charge corresponding to a difference in the voltage applied to respective electrodes, such that the first thin film transistor T1 is turned on for a time (e.g., a predetermined time).

When the emission control signal is applied to the emission control line EM, the fifth thin film transistor T5 and the sixth thin film transistor T6 are each turned on and thus the driving voltage Vel, corresponding to the driving signal from the driving power line ELVDD, is supplied to the first thin film transistor T1 through the fifth thin film transistor T5.

A driving current Id, which corresponds to a difference between the voltage supplied to the first gate electrode G1 and the driving voltage Vel, stored in the storage capacitor Cst, flows in the first drain electrode D1 of the first thin film transistor T1 while the driving voltage Vel passes through the first thin film transistor T1, which is turned on by the storage capacitor Cst and the driving current Id, is supplied to the organic light emitting diode (OLED) through the sixth thin film transistor T6, such that the organic light emitting diode (OLED) emits light for a time (e.g., a predetermined time).

The pixel circuit of the organic light emitting diode display according to an exemplary embodiment is configured to include the first thin film transistor T1 through the seventh thin film transistor T7, the storage capacitor Cst, the first scan line Sn through the third scan line Sn-2, the data line DA, the driving power line ELVDD, and the initialization power line Vint, but is not limited thereto, and a pixel circuit of an organic light emitting diode display according to another exemplary embodiment may be configured to include a plurality of thin film transistors, which are at least two, at least one capacitor, and wirings including at least one scan line and at least one driving power line.

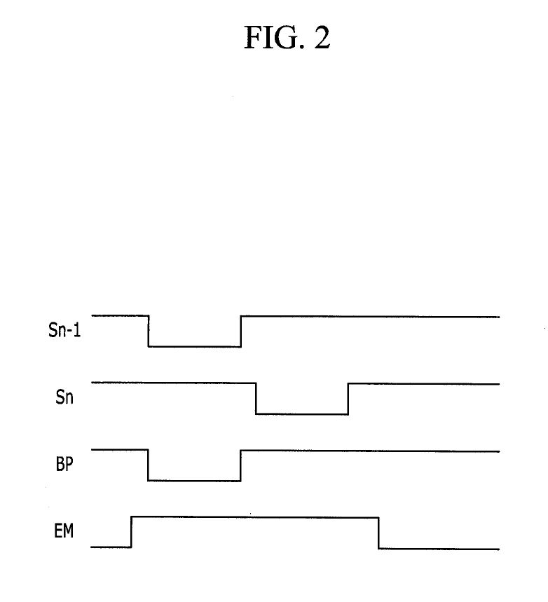

Hereinafter, a detailed operation process of one pixel of the organic light emitting diode display according to an exemplary embodiment will be described in detail with reference to FIG. 2.

FIG. 2 is a timing diagram of signals applied to one pixel of the organic light emitting diode display according to an exemplary embodiment.

As illustrated in FIG. 2, a low-level previous stage scan signal Sn-1 is supplied through the previous stage scan line 152 for an initialization period. The initialization transistor T4 is turned on by the low-level previous stage scan signal Sn-1, the initialization voltage Vint is connected to the gate electrode G1 of the driving transistor T1 from the initialization voltage line 192 through the initialization transistor T4, and the driving transistor T1 is initialized by the initialization voltage Vint.

The low-level scan signal Sn is supplied through the scan line 151 for a data programming period. The switching transistor T2 and the compensation transistor T3 are turned on by the low-level scan signal Sn. The driving transistor T1 is diode-connected by the turned on compensation transistor T3 and is forward-biased.

A compensation voltage (Dm+Vth) (Vth is a negative value), which is reduced by as much as a threshold voltage (Vth) of the driving transistor T1 from the data signal Dm supplied from the data line 171, is applied to the gate electrode G1 of the driving transistor T1. The driving voltage ELVDD and the compensation voltage Dm+Vth are applied to respective terminals of the storage capacitor Cst and a charge, corresponding to the difference in voltage between the terminals of the storage capacitor Cst, is stored in the storage capacitor Cst.

The emission control signal EM supplied from the emission control line 153 is changed from a high level to a low level for an emission period. The operation control transistor T5 and the light emission control transistor T6 are turned on by the low-level emission control signal EM for the emission period.

A driving current Id, corresponding to a voltage difference between the gate voltage Vg of the gate electrode G1 of the driving transistor T1 and the driving voltage ELVDD, is generated and the driving current Id is supplied to the organic light emitting diode (OLED) through the light emission control transistor T6. A driving gate-source voltage Vgs of the driving transistor T1 is maintained at ‘(Dm+Vth)−ELVDD’ by the storage capacitor Cst for the emission period and, depending on a current-voltage relationship of the driving transistor T1, the driving current Id is proportional to a square of a value obtained by subtracting the threshold voltage from the driving gate-source voltage (Dm−ELVDD)². Therefore, the driving current Id is determined independent of the threshold voltage Vth of the driving transistor T1.

The bypass transistor T7 receives a bypass signal BP from the bypass control line 158. The bypass signal BP is a level (e.g., a predetermined level) of voltage which may always turn off the bypass transistor T7 and the bypass transistor T7 receives a voltage having a transistor off level at the gate electrode G7, such that the bypass transistor T7 is always turned off when the bypass signal BP having the turn-off level is applied and some of the driving current Id exits to a bypass current Ibp through the bypass transistor T7 in the state in which the bypass transistor T7 is turned off.

When the organic light emitting diode (OLED) emits light even though a small (e.g., minimum) current of the driving transistor T1 for displaying a black image flows as a driving current, the black image is not properly displayed. Therefore, the bypass transistor T7 of the foldable display device, according to an exemplary embodiment, may disperse some of the minimum current of the driving transistor T1 to other suitable current paths other than a current path of the organic light emitting diode, as the bypass current Ibp. Here, the minimum current of the driving transistor T1 refers to a current when the driving gate-source voltage Vgs of the driving transistor T1 is smaller than the threshold voltage Vth, and thus the driving transistor T1 is turned off. The minimum driving current (e.g., current which is equal to or less than 10 pA), when the driving transistor T1 is turned off, is transferred to the organic light emitting diode (OLED) and is represented by a black image. When the minimum driving current representing the black image flows, the effect of the bypass transfer of the bypass current Ibp is large and when a large driving current representing an image like a general image or a white image flows, an effect of the bypass current Ibp may be small (e.g., minimal). Therefore, when the driving current representing the black image flows, a light emitting current loled of the organic light emitting diode (OLED), which is reduced as much as a current amount of the bypass current Ibp which exits from the driving current Id through the bypass transistor T7, has a minimum current amount at a level to certainly represent the black image. Therefore, the accurate black image is achieved by using the bypass transistor T7 to improve a contrast ratio. In FIG. 2, the bypass signal BP is the same or substantially the same as the previous stage scan signal Sn-1, but is not necessarily limited thereto.

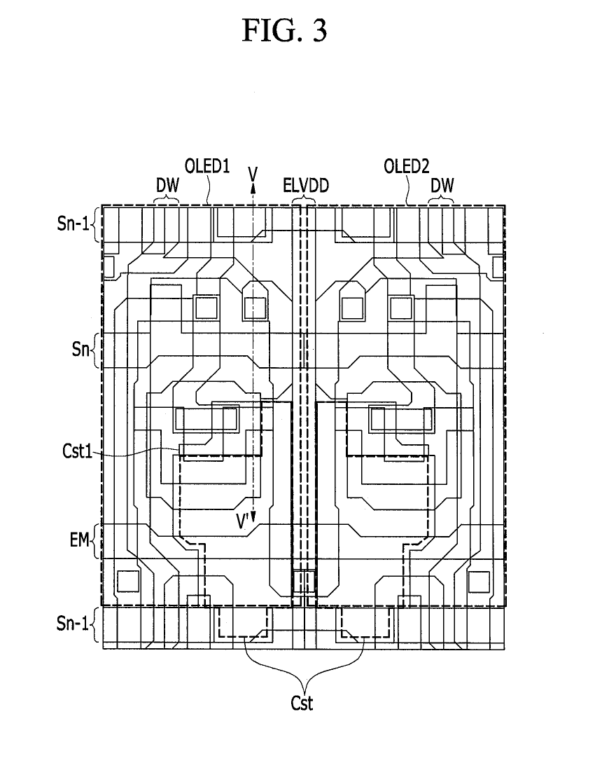

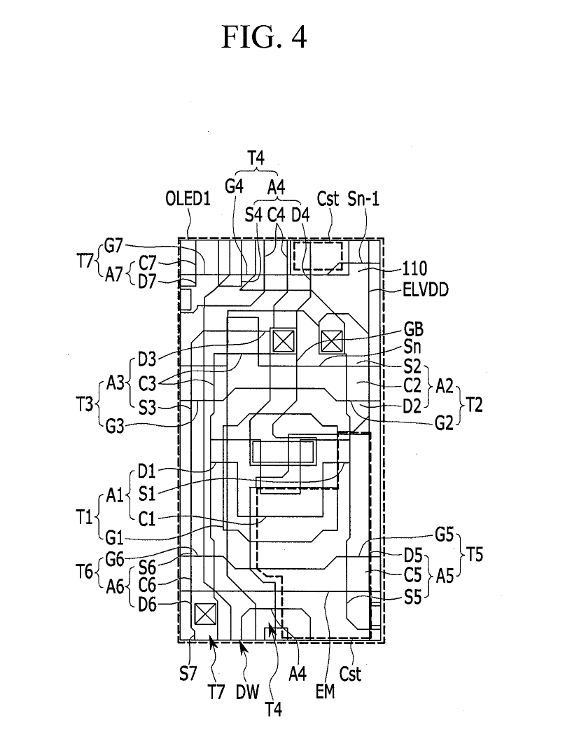

A disposition of a pixel of the organic light emitting diode display, according to the exemplary embodiment as described above, will be described with reference to FIGS. 3 and 4.

FIG. 3 is a diagram schematically illustrating a plurality of transistors and a capacitor of an organic light emitting diode display according to another exemplary embodiment. FIG. 4 is a layout view illustrating one pixel OLED1 of an organic light emitting diode display according to the exemplary embodiment illustrated in FIG. 3.

Referring to FIG. 3, the organic light emitting diode display according to an exemplary embodiment includes a plurality of pixels OLED, in which each of the pixels OLED1 and OLED2 has a symmetrical structure.

As illustrated in FIG. 3, each of the pixels OLED1 and OLED2 is provided with the scan lines Sn and Sn-1, the emission control line EM, the driving power line ELVDD, a data wire DW, and/or the like. Further, the driving power line ELVDD and the data wire DW, which are included in each of the pixels OLED1 and OLED2, have a symmetrical structure.

Further, the driving power line ELVDD is a single wiring and has a symmetrical structure between the first pixel OLED1 and the second pixel OLED2. Further, the driving power line ELVDD forms one electrode of the storage capacitor Cst. The driving power line ELVDD forms the storage capacitor Cst along with a first storage electrode Cst1.

Hereinafter, the first pixel OLED1 of the organic light emitting diode display will be described in detail with reference to FIG. 4, and the second pixel OLED2 is the same or substantially the same as the first pixel OLED1 and therefore the description thereof will be omitted.

As illustrated in FIGS. 1, 3 and 4, the organic light emitting diode display according to an exemplary embodiment includes a substrate 110, the first thin film transistor T1, the second thin film transistor T2, the third thin film transistor T3, the fourth thin film transistor T4, the fifth thin film transistor T5, the sixth thin film transistor T6, the seventh thin film transistor T7, the first scan line Sn, the second scan line Sn-1 or the third scan line Sn-2, the emission control line EM, the storage capacitor Cst, the data line DA, the driving power line ELVDD, and the gate bridge GB, which are the data wiring DW, the initialization power line Vint, and the organic light emitting diode (OLED).

In FIG. 3, the second scan line Sn-1 and the third scan line Sn-2 are illustrated as one scan line, but are not limited thereto, and the second scan line Sn-1 and the third scan line Sn-2 may be positioned as the respective scan lines, which are spaced apart from each other.

The substrate 110 may be made of glass, quartz, ceramic, sapphire, plastic, metal, and/or the like, and may be flexible, stretchable, rollable, and/or foldable. The substrate SUB is flexible, stretchable, rollable, and/or foldable and thus the organic light emitting diode display may be flexible, stretchable, rollable, and/or foldable on the whole.

The first thin film transistor T1 is positioned on the substrate SUB and includes a first active pattern A1 and a first gate electrode G1.

The first active pattern A1 includes a first source electrode S1, a first channel C1, and a first drain electrode D1. The first source electrode S1 is connected to the second drain electrode D2 of the second thin film transistor T2 and the fifth drain electrode D5 of the fifth thin film transistor T5, and the first drain electrode D1 is connected to the third source electrode S3 of the third thin film transistor T3 and the sixth source electrode S6 of the sixth thin film transistor T6. The first channel C1, which is a channel region of the first active pattern A1 overlapping the first gate electrode G1, is bent at least once and extends within a space overlapping the first gate electrode G1, which is a limited space and thus the length of the first channel C1 may be formed to be long, such that a driving range of a gate voltage applied to the first gate electrode G1, may be formed to be wide. As a result, a magnitude of the gate voltage applied to the first gate electrode G1 is changed within the wide driving range to more delicately control gray light emitted from the organic light emitting diode (OLED), thereby improving a quality of image that is displayed from the organic light emitting diode display. A shape of the first active pattern A1 may be variously changed and may be changed in various suitable forms such as ‘inverse S’, ‘S’, ‘M’, and ‘W’.

The first active pattern A1 may be made of poly-silicon or oxide semiconductor. The oxide semiconductor may include an oxide of titanium (Ti), hafnium (Hf), zirconium (Zr), aluminum (Al), tantalum (Ta), germanium (Ge), zinc (Zn), gallium (Ga), tin (Sn), indium (In), or combinations thereof. For example, The oxide semiconductor may include a zinc oxide (ZnO), an indium-gallium-zinc oxide (InGaZnO4), an indium-zinc oxide (Zn—In—O), a zinc-tin oxide (Zn—Sn—O), an indium-gallium oxide (In—Ga—O), an indium-tin oxide (In—Sn—O), an indium-zirconium oxide (In—Zr—O), an indium-zirconium-zinc oxide (In—Zr—Zn—O), an indium-zirconium-tin oxide (In—Zr—Sn—O), an indium-zirconium gallium oxide (In—Zr—Ga—O), an indium-aluminum oxide (In—Al—O), an indium-zinc-aluminum oxide (In—Zn—Al—O), an indium-tin-aluminum oxide (In—Sn—Al—O), an indium-aluminum-gallium oxide (In—Al—Ga—O), an indium-tantalum oxide (In—Ta—O), an indium-tantalum-zinc oxide (In—Ta—Zn—O), an indium-tantalum-tin oxide (In—Ta—Sn—O), an indium-tantalum-gallium oxide (In—Ta—Ga—O), an indium-germanium oxide (In—Ge—O), an indium-germanium-zinc oxide (In—Ge—Zn—O), an indium-germanium-tin oxide (In—Ge—Sn—O), an indium-germanium-gallium oxide (In—Ge—Ga—O), a titanium-indium-zinc oxide (Ti—In—Zn—O), a hafnium -indium-zinc oxide (Hf—In—Zn—O), and combinations thereof, which are composite oxides. When the first active pattern A1 is made of the oxide semiconductor, a separate passivation layer may be added in order to protect the oxide semiconductor, which is vulnerable to an external environment such as a high temperature, and/or the like.

The first channel C1 of the first active pattern A1 may be channel-doped with N type impurities or P type impurities and the first source electrode S1 and the first drain electrode D1 are spaced apart from each other, having the first channel C1 therebetween, and may each be doped with doping impurities having an opposite type to the doping impurities doped in the first channel C1.

The first gate electrode G1 is positioned on the first channel C1 of the first active pattern A1 and has an island shape. The first gate electrode G1 is positioned on the interlayer insulating layer ILD and is connected to the fourth drain electrode D4 of the fourth thin film transistor T4 and the third drain electrode D3 of the third film transistor T3. The first gate electrode G1 overlaps a storage capacitor electrode CE and may also serve as the other electrode of the storage capacitor Cst while serving as the gate electrode of the first thin film transistor T1. That is, the first gate electrode G1 forms the storage capacitor Cst, along with the storage capacitor electrode CE. The first gate electrode G1 may be made of metal.

The second thin film transistor T2 is positioned on the substrate 110 and includes the second active pattern A2 and the second gate electrode G2.

The second active pattern A2 includes a second source electrode S2, a second channel C2, and a second drain electrode D2. The second source electrode S2 is connected to the data line DA and the second drain electrode D2 is connected to the first source electrode S1 of the first thin film transistor T1. The second channel C2, which is a channel region of the second active pattern A2 overlapping the second gate electrode G2, is positioned between the second source electrode S2 and the second drain electrode D2. That is, the second active pattern A2 is connected to the first active pattern A1.

The second channel C2 of the second active pattern A2 may be channel-doped with N type impurities or P type impurities and the second source electrode S2 and the second drain electrode D2 are spaced apart from each other, having the first channel C1 therebetween, and may each be doped with doping impurities having an opposite type to the doping impurities doped in the first channel C1. The second active pattern A2 is positioned on the same layer as the first active pattern A1, made of the same material as the first active pattern A1, and is integrally formed with the first active pattern A1.

The second gate electrode G2 is positioned on the second channel C2 of the second active pattern A2 and is integrally formed with the first scan line Sn.

The third thin film transistor T3 is positioned on the substrate 110 and includes the third active pattern A3 and the second gate electrode G3.

The third active pattern A3 includes the third source electrode S3, the third channel C3, and the third drain electrode D3. The third source electrode S3 is connected to the first drain electrode D1 and the third drain electrode D3 is connected to the first gate electrode G1 of the first thin film transistor T1. The third channel C3, which is a channel region of the third active pattern A3 overlapping the third gate electrode G3, is positioned between the third source electrode S3 and the third drain electrode D3. That is, the third active pattern A3 connects between the first active pattern A1 and the first gate electrode G1.

The third channel C3 of the third active pattern A3 may be channel-doped with N type impurities or P type impurities and the third source electrode S3 and the third drain electrode D3 are spaced apart from each other, having the first channel C3 therebetween, and may each be doped with doping impurities opposite to the doping impurities doped in the third channel C3. The third active pattern A3 is positioned on the same layer as the first active pattern A1 and the second active pattern A2, made of the same material as the first active pattern A1 and the second active pattern A2, and is integrally formed with the first active pattern A1 and the second active pattern A2.

The third gate electrode G3 is positioned on the third channel C3 of the third active pattern A3 and is integrally formed with the first scan line Sn. The third gate electrode G3 is formed as a dual gate electrode.

The fourth thin film transistor T4 is positioned on the substrate SUB and includes a fourth active pattern A4 and the fourth gate electrode G4.

The fourth active pattern A4 includes a fourth source electrode S4, a fourth channel C4, and a fourth drain electrode D4. The fourth source electrode S4 is connected to the initialization power line Vint through the contact hole and the fourth drain electrode D4 is connected to the first gate electrode G1 of the first thin film transistor T1. The fourth channel C4, which is a channel region of the fourth active pattern A4 overlapping the fourth gate electrode G4, is positioned between the fourth source electrode S4 and the fourth drain electrode D4. That is, the fourth active pattern A4 is connected to the third active pattern A3 and the first gate electrode G1, and concurrently (e.g., simultaneously) connected between the initialization power line Vint and the first gate electrode G1.

The fourth channel C4 of the fourth active pattern A4 may be channel-doped with N type impurities or P type impurities and the fourth source electrode S4 and the fourth drain electrode D4 are spaced apart from each other, having the fourth channel C4 therebetween, and may each be doped with doping impurities having an opposite type to the doping impurities doped in the fourth channel C4. The fourth active pattern A4 is positioned on the same layer as the first active pattern A1, the second active pattern A2, and the third active pattern A3, made of the same material as the first active pattern A1, the second active pattern A2, and the third active pattern A3, and is integrally formed with the first active pattern A1, the second active pattern A2, and the third active pattern A3.

The fourth gate electrode G4 is positioned on the fourth channel C4 of the fourth active pattern A4 and is integrally formed with the second scan line Sn-1. The fourth gate electrode G4 is formed as a dual gate electrode.

The fifth thin film transistor T5 is positioned on the substrate (SUB) and includes a fifth active pattern A5 and the fifth gate electrode G5.

The fifth active pattern A5 includes a fifth source electrode S5, a fifth channel C5, and a fifth drain electrode D5

The fifth source electrode S5 is connected to the driving power line ELVDD and the fifth drain electrode D5 is connected to the first source electrode S1 of the first thin film transistor T1. The fifth channel C5, which is a channel region of the fifth active pattern A5 overlapping the fifth gate electrode G5, is positioned between the fifth source electrode S5 and the fifth drain electrode D5. That is, the fifth active pattern A5 connects between the driving power line ELVDD and the first active pattern A1.

The fifth channel C5 of the fifth active pattern A5 may be channel-doped with N type impurities or P type impurities and the fifth source electrode S5 and the fifth drain electrode D5 are spaced apart from each other, having the fifth channel C5 therebetween, and may each be doped with doping impurities having an opposite type to the doping impurities doped in the fifth channel C5. The fifth active pattern A5 is positioned on the same layer as the first active pattern A1, the second active pattern A2, the third active pattern A3, and the fourth active pattern A4, made of the same material as the first active pattern A1, the second active pattern A2, the third active pattern A3, and the fourth active pattern A4, and is integrally formed with the first active pattern A1, the second active pattern A2, the third active pattern A3, and the fourth active pattern A4.

The fifth gate electrode G5 is positioned on the fifth channel C5 of the fifth active pattern A5 and is integrally formed with the emission control line EM.

The sixth thin film transistor T6 is positioned on the substrate SUB and includes a sixth active pattern A6 and a sixth gate electrode G6.

The sixth active pattern A6 includes a sixth source electrode S6, a sixth channel C6, and a sixth drain electrode D6. The sixth source electrode S6 is connected to the first drain electrode D1 of the first thin film transistor T1, and the sixth drain electrode D6 is connected to the first electrode E1 of the organic light emitting diode (OLED) through the contact hole. The sixth channel C6, which is a channel region of the sixth active pattern A6 overlapping the sixth gate electrode G6, is positioned between the sixth source electrode S6 and the sixth drain electrode D6. That is, the sixth active pattern A6 connects between the first active pattern A1 and the first electrode E1 of the organic light emitting diode (OLED).

The sixth channel C6 of the sixth active pattern A6 may be channel-doped with N type impurities or P type impurities and the sixth source electrode S6 and the sixth drain electrode D6 are spaced apart from each other, having the sixth channel C6 therebetween, and may each be doped with doping impurities having an opposite type to the doping impurities doped in the sixth channel C6. The sixth active pattern A6 is positioned on the same layer as the first active pattern A1, the second active pattern A2, the third active pattern A3, the fourth active pattern A4, and the fifth active pattern A5, made of the same material of the first active pattern A1, the second active pattern A2, the third active pattern A3, the fourth active pattern A4, and the fifth active pattern A5, and is integrally formed with the first active pattern A1, the second active pattern A2, the third active pattern A3, the fourth active pattern A4, and the fifth active pattern A5.

The sixth gate electrode G6 is positioned on the sixth channel C6 of the sixth active pattern A6 and is integrally formed with the emission control line EM.

The seventh thin film transistor T7 is positioned on the substrate SUB and includes a seventh active pattern A7 and a seventh gate electrode G7.

The seventh active pattern A7 includes a seventh source electrode S7, a seventh channel C7, and a seventh drain electrode D7. The seventh source electrode S7 is connected to the first electrode of the organic light emitting diode of another pixel (pixel positioned over the pixel of FIG. 2) and the seventh drain electrode D7 is connected to the fourth source electrode S4 of the fourth thin film transistor T4. The seventh channel C7, which is a channel region of the seventh active pattern A7 overlapping the seventh gate electrode G7, is positioned between the seventh source electrode S7 and the seventh drain electrode D7. That is, the seventh active pattern A7 connects between the first electrode and the fourth active pattern A4 of the organic light emitting diode.

The seventh channel C7 of the seventh active pattern A7 may be channel-doped with N type impurities or P type impurities and the seventh source electrode S7 and the seventh drain electrode D7 are spaced apart from each other, having the seventh channel C7 therebetween, and may each be doped with doping impurities opposite to the doping impurities doped in the seventh channel C7. The seventh active pattern A7 is positioned on the same layer as the first active pattern A1, the second active pattern A2, the third active pattern A3, the fourth active pattern A4, the fifth active pattern A5, and the sixth active pattern A6, made of the same material as the first active pattern A1, the second active pattern A2, the third active pattern A3, the fourth active pattern A4, the fifth active pattern A5, and the sixth active pattern A6, and is integrally formed with the first active pattern A1, the second active pattern A2, the third active pattern A3, the fourth active pattern A4, the fifth active pattern A5, and the sixth active pattern A6.

The seventh gate electrode G7 is positioned on the seventh channel C7 of the seventh active pattern A7 and is integrally formed with the third scan line Sn-2.

The first scan line Sn is positioned on the second active pattern A2 and the third active pattern A3 to extend in one direction crossing the second active pattern A2 and the third active pattern A3 and connected to the second gate electrode G2 and the third gate electrode G3, while being integrally formed with the second gate electrode G2 and the third gate electrode G3.

The second scan line Sn-1 is positioned on the fourth active pattern A4, while being spaced apart from the first scan line Sn and extends in one direction crossing the fourth active pattern A4 and connected to the fourth gate electrode G4, while being integrally formed with the fourth gate electrode G4. The second scan line Sn-1 is integrally formed with the third scan line Sn-2 but is not limited thereto, and may be formed as a different line from the third scan line Sn-2.

The third scan line Sn-2 is positioned on the seventh active pattern A7, while being spaced apart from the second scan line Sn-1 and extends in one direction crossing the seventh active pattern A7 and connected to the seventh gate electrode G7, while being integrally formed with the seventh gate electrode G7. The third scan line Sn-2 is integrally formed with the second scan line Sn-1 but is not limited thereto, and may be formed as a different line from the second scan line Sn-1.

The emission control line EM is positioned on the fifth active pattern A5 and the sixth active pattern A6, while being spaced apart from the first scan line Sn and extends in one direction crossing the fifth active pattern A5 and the sixth active pattern A6 and is connected to the fifth gate electrode G5 and the sixth gate electrode G6, while being integrally formed with the fifth gate electrode G5 and the sixth gate electrode G6.

As described above, the emission control line EM, the third scan line Sn-2, the second scan line Sn-1, the first scan line Sn, the first gate electrode G1, the second gate electrode G2, the third gate electrode G3, the fourth gate electrode G4, the fifth gate electrode G5, the sixth gate electrode G6, and the seventh gate electrode G7 are positioned on the same or substantially the same layer and made of the same material.

For example, the emission control line EM, the third scan line Sn-2, the second scan line Sn-1, the first scan line Sn, the first gate electrode G1, the second gate electrode G2, the third gate electrode G3, the fourth gate electrode G4, the fifth gate electrode G5, the sixth gate electrode G6, and the seventh gate electrode G7 may form the first gate wire.

According to another exemplary embodiment, the emission control line EM, the third scan line Sn-2, the second scan line Sn-1, the first scan line Sn, the first gate electrode G1, the second gate electrode G2, the third gate electrode G3, the fourth gate electrode G4, the fifth gate electrode G5, the sixth gate electrode G6, and the seventh gate electrode G7 each are selectively positioned on different layers and made of different materials.

The storage capacitor Cst includes one electrode and the other electrode which face each other, having the insulating layer therebetween. The above-mentioned one electrode may be the storage capacitor electrode CE and the other electrode may be the first gate electrode G1. The storage capacitor electrode CE is positioned on the first gate electrode G1 and is connected to the driving power line ELVDD. The storage capacitor electrode CE overlaps the first gate electrode G1 on the first gate electrode G1.

The storage capacitor electrode CE forms the storage capacitor Cst along with the first gate electrode G1, and the first gate electrode G1 and the storage capacitor electrode CE are each made of different materials or the same metal on different layers. The storage capacitor electrode CE extends in one direction and crosses a plurality of pixels Pxs, which are adjacent to each other. The storage capacitor electrode CE may be formed of a second gate wire, which is positioned on the above-mentioned first gate wire.

The data wire DW is positioned on the first gate wire including the first gate electrode G1 and the second gate wire including the storage capacitor electrode CE and includes the data line DA, the driving power line ELVDD, and the gate bridge GB.

The organic light emitting diode OLED includes the first electrode E1, an organic emission layer OL, and the second electrode E2. The first electrode E1 is connected to the sixth drain electrode D6 of the sixth thin film transistor T6 through the contact hole. The organic emission layer OL is positioned between the first electrode E1 and the second electrode E2. The second electrode E2 is positioned on the organic emission layer OL. At least one of the first electrode E1 and the second electrode E2 may be a light transmitting electrode, a light reflective electrode, or a light translucent electrode, and light emitted from the organic emission layer OL may be emitted in at least one direction toward the first electrode E1 and the second electrode E2.

A capping layer covering the organic light emitting diode (OLED) may be positioned on the organic light emitting diode (OLED) and a thin film encapsulation layer or an encapsulation substrate may be positioned on the organic light emitting diode (OLED), having the capping layer therebetween.

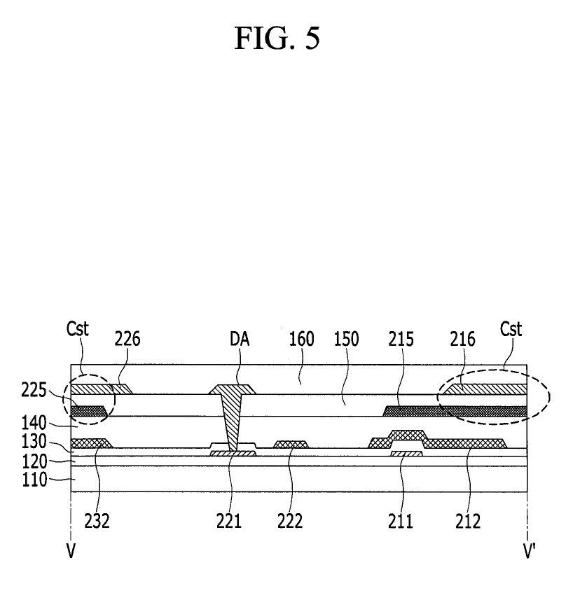

FIG. 5 is a cross-sectional view of the organic light emitting diode display of FIG. 3 taken along the line V-V′.

Referring to FIGS. 3 to 5, the organic light emitting diode display according to an exemplary embodiment includes the substrate 110, a buffer layer 120, a first gate insulating layer 130, an interlayer insulating layer (ILD) 140, a second gate insulating layer 150, a passivation layer (VIA) 160, and a pixel defined layer (PDL) covering a pixel

The buffer layer 120 is formed on the substrate 110. The substrate 110 may be formed as an insulating substrate, which is made of glass, quartz, ceramic, plastic, and/or the like. Further, the buffer layer 120 blocks or substantially blocks impurities from the substrate 110 at the time of a crystallization process for forming polysilicon to serve to improve characteristics of the polysilicon and to reduce a stress applied to the substrate 110.

As illustrated in FIG. 5, a driving active pattern 211 of the driving transistor T1 and a switching active pattern 221 of the switching transistor T2 are formed on the buffer layer 120. As such, a semiconductor including a channel, which includes a driving channel, a switching channel, a compensation channel, an initialization channel, an operation control channel, an emission control channel, and a bypass channel, is formed on the buffer layer 120.

The interlayer insulating layer 140 may be made of silicon nitride (SiNx), silicon oxide (SiO2), and/or the like. A first driving gate electrode 212 of the driving transistor T1 and a first switching gate electrode 222 of the switching transistor T2 are formed on the interlayer insulating layer 140. Further, a first gate electrode 232 connected to the second scan line Sn-1 is formed on the interlayer insulating layer 140.

The second gate insulating layer 150 is formed on the interlayer insulating layer 140. The second gate insulating layer 150 includes a second driving gate electrode 215 of the driving transistor T1.

The passivation layer 160 is formed on the second gate insulating layer 150. Further, the passivation layer 160 may be formed of an organic layer. The driving power lines 216 and 266 and the data line DA of the switching transistor T2 are formed on the passivation layer 160.

Further, in the organic light emitting diode display according to an exemplary embodiment, the driving power line 216 and 266 forms the storage electrode of the storage capacitor Cst together with the second driving gate electrode 215. Here, the driving power line ELVDD may form the storage electrode along with the driving gate electrode of the driving transistor T1.

The driving transistor T1 includes the first driving gate electrode 212 formed on the interlayer insulating layer 140 and the second driving gate electrode 215 formed on the second gate insulating layer 150. Further, the second driving gate electrode 215 forms the storage electrode of the storage capacitor Cst along with the first driving power line 216. The first driving power line 216 may be formed on the second gate insulating layer 150, may overlap the second driving gate electrode 215, and may be formed on the passivation layer 160.

Further, the storage capacitor Cst may be formed of the gate electrode 225 formed on the second gate insulating layer 150 and the second driving power line 226 formed on the passivation layer 160 while being overlapped therewith. Here, the gate electrode 225 formed on the second gate insulating layer 150 may form the first storage electrode Cst1, and the second driving power line 226 may form the second storage electrode.

As described above, in an organic light emitting diode display in accordance with an exemplary embodiment, it is possible to reduce or minimize the crosstalk and improve the driving characteristics by using the driving power line as the storage electrode of the storage capacitor to increase the capacity of the storage capacitor.

The foregoing exemplary embodiments are not implemented only by an apparatus and a method, and therefore, may be realized by programs realizing functions corresponding to the configuration of an exemplary embodiment or recording media on which the programs are recorded. A person of skill in the art should also recognize that the process may be executed via hardware, firmware (e.g. via an ASIC), or in any combination of software, firmware, and/or hardware. Furthermore, the sequence of steps of the process is not fixed, but can be altered into any desired sequence as recognized by a person of skill in the art. The altered sequence may include all of the steps or a portion of the steps.

Relevant devices or components according to embodiments of the present invention described herein may be implemented utilizing any suitable hardware, firmware (e.g. an application-specific integrated circuit), software, or a suitable combination of software, firmware, and hardware. For example, various components may be formed on one integrated circuit (IC) chip or on separate IC chips. Further, various components may be implemented on a flexible printed circuit film, a tape carrier package (TCP), a printed circuit board (PCB), or formed on a same substrate as one or more circuits and/or devices. Further, various components may be a process orthread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

While this invention has been described in connection with what is presently considered to be practical exemplary embodiments, it is to be understood that the invention is not limited to the disclosed embodiments, but, on the contrary, is intended to cover various suitable modifications and equivalent arrangements included within the spirit and scope of the appended claims, and their equivalents.

What is claimed is:

1. An organic light emitting diode display, comprising:
a substrate;
a scan line on the substrate configured to transfer a scan signal;
a data line crossing the scan line configured to transfer a data voltage;
a driving power line crossing the scan line configured to transfer a driving voltage;
a switching transistor connected to the scan line and the data line;
a driving transistor connected to the switching transistor; and
an organic light emitting diode electrically connected to the driving transistor,
wherein the driving power line is a storage electrode of a storage capacitor.

2. The organic light emitting diode display of claim 1,
wherein the driving power line forms the storage capacitor together with a driving gate electrode of the driving transistor.

3. The organic light emitting diode display of claim 2, further comprising:
a first gate insulating layer, an interlayer insulating layer, and a second gate insulating layer that are sequentially stacked on the substrate, and
wherein the driving transistor comprises:
a first driving gate electrode on the interlayer insulating layer; and
a second driving gate electrode on the second gate insulating layer.

4. The organic light emitting diode display of claim 3, wherein:
the second driving gate electrode, along with the driving power line, forms the storage electrode of the storage capacitor.

5. The organic light emitting diode display of claim 4,
wherein the driving power line overlaps the second driving gate electrode on a second driving insulating layer.

6. The organic light emitting diode display of claim 1, further comprising:
an interlayer insulating layer, a gate insulating layer, and a passivation layer that are sequentially stacked on the substrate,
wherein the storage capacitor comprises:
a first storage electrode as a gate electrode on the gate insulating layer; and
a second storage electrode as the driving power line.

7. The organic light emitting diode display of claim 6,
wherein the driving power line is on the passivation layer.

8. The organic light emitting diode display of claim 7,
wherein the driving power line is the second storage electrode and overlaps the gate electrode.
